(19) United States
(12) Patent Application Publication
(10) Pub. No.: US 2007/0176623 A1
(43) Pub. Date: Aug. 2, 2007

(54) Method and apparatus for testing a TFT array for a liquid crystal panel

(75) Inventor: Yasuhiro Miyake, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/518,767

(22) Filed: Sep. 11, 2006

(30) Foreign Application Priority Data
Jan. 27, 2006 (JP) 2006-018352

(51) Int. Cl. G01R 31/00

(52) U.S. Cl. 324/770

(57) ABSTRACT

A method for testing a liquid crystal display panel wherein there are, disposed in matrix form, pixels comprising liquid crystal elements in which a liquid crystal material is sealed between opposing electrodes, this method for testing a liquid crystal display panel being characterized in that it comprises a first charging step for applying a first voltage between the opposing electrodes of the liquid crystal element of the pixel under test; a second charging step for applying a second voltage of the opposite polarity of the first voltage between the opposing electrodes of the liquid crystal element of the pixel under test; and a measuring step for discharging the charge that has accumulated in the electrodes of the liquid crystal element of the pixel under test after the second charging step, and measuring the amount of charge discharged.

### 1. FIELD OF THE INVENTION

The present disclosure relates to a manufacturing method and a testing method for a display panel, as well as an apparatus for testing a display panel, and in particular, to a method for manufacturing a liquid crystal display panel in which liquid crystals are sealed.

### 2. DISCUSSION OF THE BACKGROUND ART

The most popular displays that use liquid crystal materials comprise a backlight as the light source, a deflection filter through which passes only light of a constant polarization; and color filters that create the three primary colors. Of these, the general structure of the display panel is such that liquid crystal elements are disposed on an active matrix substrate wherein transistors, a holding capacitor, and other elements are formed for each pixel on a glass sheet or other substrate.

FIG. 2 shows the structure of a liquid crystal element 233 of a typical liquid crystal panel. Liquid crystal element 233 comprises a liquid crystal material 302; orientation films 301 and 303 disposed such that they sandwich liquid crystal material 302 from both sides; and two opposing electrodes 300 and 304 disposed such that they further sandwich the outside of orientation films 301 and 303. One of the pair of electrodes, electrode 304, is disposed on a TFT substrate.

Liquid crystal element 233 has the function of turning the polarized light of incident light 90 degrees when voltage in not applied between electrodes 300 and 304 and allowing incident light through in the original polarized state when voltage is applied. Liquid crystal panels use this function to control the blocking/transmission status of light by allowing light with the same direction of polarization to shine on liquid crystal element 233 and input light that has passed through liquid crystal element 233 to a deflection filter once again. Consequently, the group of molecules of liquid crystal material 302 of liquid crystal element 233 cannot accurately control the blocking/transmission status of light when no voltage is applied unless they are oriented in a specific direction. Therefore, oriented films 301 and 303 are disposed in between each electrode 300 and 304 and liquid crystal material 302 and the group of molecules of the liquid crystals are oriented in a specific direction.

However, the pixels on the liquid crystal display panel should all have the same properties, but it is difficult to form a panel with stable properties over a panel region with a wide physical surface area by the current production technology. Defects are generated for a variety of reasons, such as the following: impurities enter the region in which the liquid crystals are produced, the space between opposing electrodes 300 and 304 is not uniform, defects are generated during the formation of orientation films 301 and 304, liquid crystal material 302 itself is not uniform, and similar reasons. Therefore, it is necessary to check the liquid crystal display panel for predetermined properties during the final steps in the production of the panel.

Examples of such a testing method are methods that use optical photographic or macroscopic testing of a panel, as in JP Unexamined Patent Application (Kokai) 2005-55196, and methods that use electrical testing whereby a panel is checked for defects by measuring the electrostatic capacity of the liquid crystal elements. Electrical measurement has advantages in that, when compared to optical measurement, the apparatus structure is simple and the time needed for measurement is short.

The defects in a liquid crystal panel can be divided into defects under the steady state (defects in static properties) such that the amount of light blocking (or transmission) is insufficient, and the like, and defects during the course leading to the steady state (defects in dynamic properties) such that response is delayed. Of these, the defects in static properties can be detected by methods for measuring the electrostatic capacity under the steady state as described above, but defects in dynamic properties cannot be detected simply by measuring electrostatic capacity under the steady state.

For instance, the case when there is a defect in part of orientation films 301 and 304 or there is a defect such that the panel contains liquid crystal material with a delayed response are virtually no different from the case of defect-free electrostatic capacity under the steady state. Therefore, it is extremely difficult to detect such cases. Consequently, there is a need for a testing method with which it is possible to detect defects arising from the dynamic properties of a liquid crystal panel using electrical measurement methods.

### SUMMARY OF THE INVENTION

A method for testing a liquid crystal display panel wherein there are, disposed in matrix form, pixels comprising liquid crystal elements in which a liquid crystal material is sealed between opposing electrodes, this method for testing a liquid crystal display panel being characterized in that it comprises a first charging step for applying a first voltage between the opposing electrodes of the liquid crystal element of the pixel under test; a second charging step for applying a second voltage with polarity opposite to the first voltage between the opposing electrodes of the liquid crystal element of the pixel under test; and a measuring step for discharging the charge that has accumulated in the electrodes of the liquid crystal element of the pixel under test after the second charging step, and measuring the amount of charge discharged.

That is, it is possible to detect the dynamic electrical properties of a liquid crystal element by checking to what extent a liquid crystal element has accumulated a charge immediately after a voltage that will apply a field in the opposite direction has been applied to a liquid crystal to which a field in a predetermined direction has been pre-applied. A liquid crystal element having a poor response from groups of molecules will also have a poor electrical response. Therefore, it is possible to detect defective pixels with a poor response from groups of molecules by detecting the electrical properties. It is possible to prevent testing-related deterioration of the liquid crystal element by bringing the voltage that is applied to supply the charge that will be detected to the voltage that is of the opposite polarity, but is of the same absolute value as the preapplied voltage.

An additional embodiment includes a method for testing a liquid crystal panel wherein there are, disposed in matrix form, pixels having liquid crystal elements in which a liquid crystal material is sealed between opposing electrodes, this method for testing a liquid crystal display panel being characterized in that it comprises a charging step for applying a test voltage between the opposing electrodes of the liquid crystal element of the pixel under test and a measuring step for discharging the charge that has accumulated in the electrodes of the liquid crystal element and finding changes over time in the amount of charge discharged.

That is, it is possible to find the dynamic electrical properties of the liquid crystal element in question by measuring changes over time in the charge that is discharged from the liquid crystal element. In general, a liquid crystal element having a poor response from groups of molecules will also have a poor electrical response. Therefore, it is possible to detect pixels with a slow response by detecting the electrical response of the liquid crystal elements. Precision testing becomes possible because the amount of change in the high S/N ratio can be found by finding the amount of change in two measurements, one immediately after discharge and the other when virtually the steady state is reached.

The present disclosure makes it possible to provide a method with which it is possible to precisely check for defects based on the dynamic properties of a liquid crystal display panel, etc.

### BRIEF DESCRIPTION OF THE DRAWINGS

FIG. 1 is a drawing of the testing apparatus of the present disclosure.

FIG. 2 is a drawing of the liquid crystal display panel under test.

FIG. 3 is a flow chart of the operation of the first embodiment.

FIG. 4 is a flow chart of the operation of the second embodiment.

### DETAILED DESCRIPTION OF THE PREFERRED EMBODIMENT

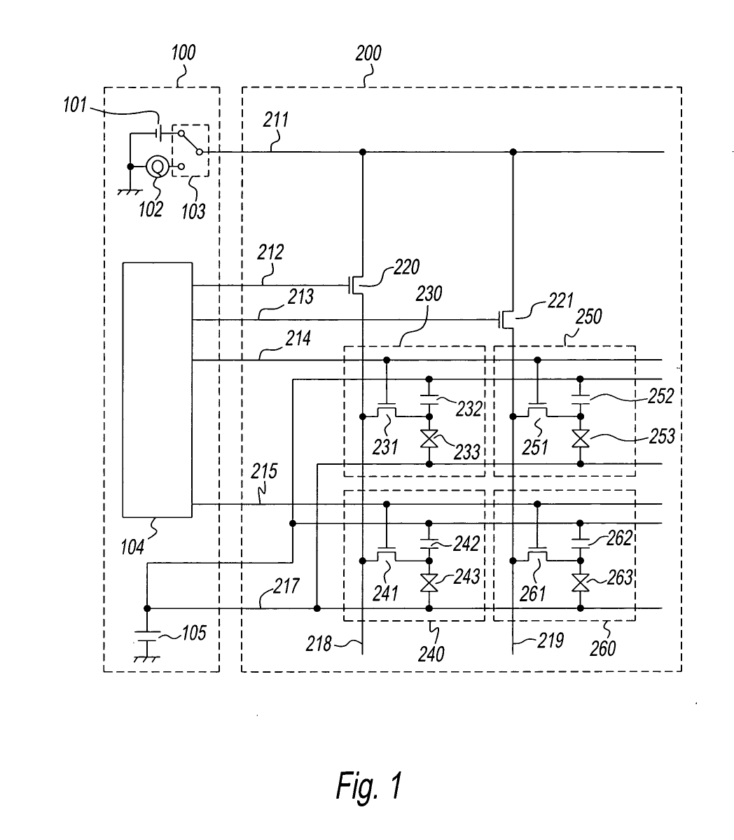

A typical example of the present disclosure will be described while referring to the drawings. FIG. 1 is a drawing of a testing apparatus 100 of the present disclosure connected to the device under test, a liquid crystal display panel 200.

Liquid crystal display panel 200 comprises control lines 212, 213, 214, and 215 for selecting pixels, signal lines 218 and 219 that intersect each of the control lines and transmit signals that control the status of the pixels, a transistor 220 for controlling the connection status between a signal input line 211 and signal line 218 from the outside based on the input of control line 212, a transistor 221 that controls the connection status between signal input line 211 and signal line 219 based on the input of control line 213, pixels (230, 240, etc) disposed where the control lines and signal lines intersect, and a common line 217 for applying a reference potential to pixel holding capacitors (232, 242, etc.) and liquid crystal elements (233, 243, etc.).

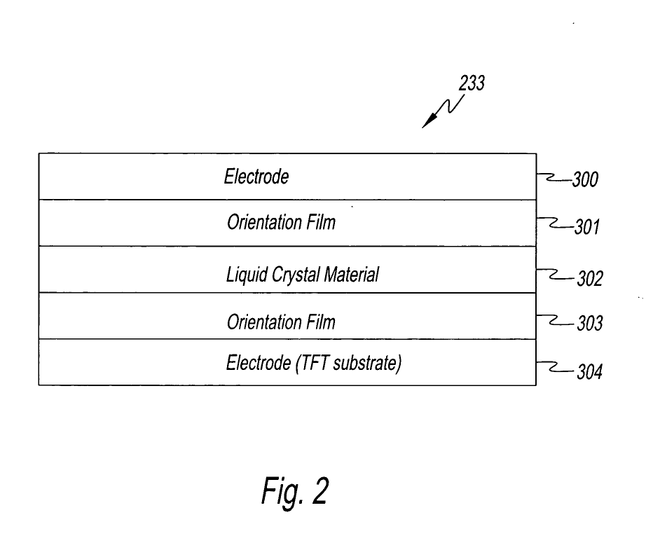

A pixel 230 comprises a transistor 231, which is a switching element whose gate terminal is connected to control line 214 and whose drain terminal is connected to signal line 218, and holding capacitor 232 connected in series to the source terminal of transistor 231. The other end of holding capacitor 232 is connected to common line 217. Moreover, the electrode of liquid crystal 233 on the side of the TFT active matrix substrate (electrode 304 in FIG. 2) is connected to the source terminal of transistor 231 and the opposing electrode 300 is connected to common line 217.

The structure of the part of each pixel element in which liquid crystal material is sealed is the same as the structure in above-mentioned FIG. 2. Moreover, the structure of the other pixels (240, 250, etc.) inside liquid crystal panel 200 is the same as the structure of pixel 230.

It should be noted that functional elements other than transistors can be changed as needed as long as switching elements (231, 241, etc.) have the function of being capable of controlling the connection status between signal line 218 and liquid crystal element 233. Moreover, transistors 220 and 221 can be changed to shift registers, and similar devices, as long as they have the function of controlling the connection status between signal input line 221 and signal lines 218 and 219.

Liquid crystal display panel 200 is connected to testing apparatus 100. Testing apparatus 100 comprises a control device 104 for selecting the pixel under test and controlling the operation of the testing apparatus; power sources 101 and 105 for applying voltage to the liquid crystal element of the pixel under test; a charge meter 102 for measuring the amount of charge discharged from the pixel under test and determining if there are defects in the liquid crystal element; and a switching element 103 for selectively connecting power source 101 and charge meter 102 to signal input line 211. Control lines 212, 213, 214, and 215 are connected to control device 104. Moreover, common line 217 is connected to power source 105.

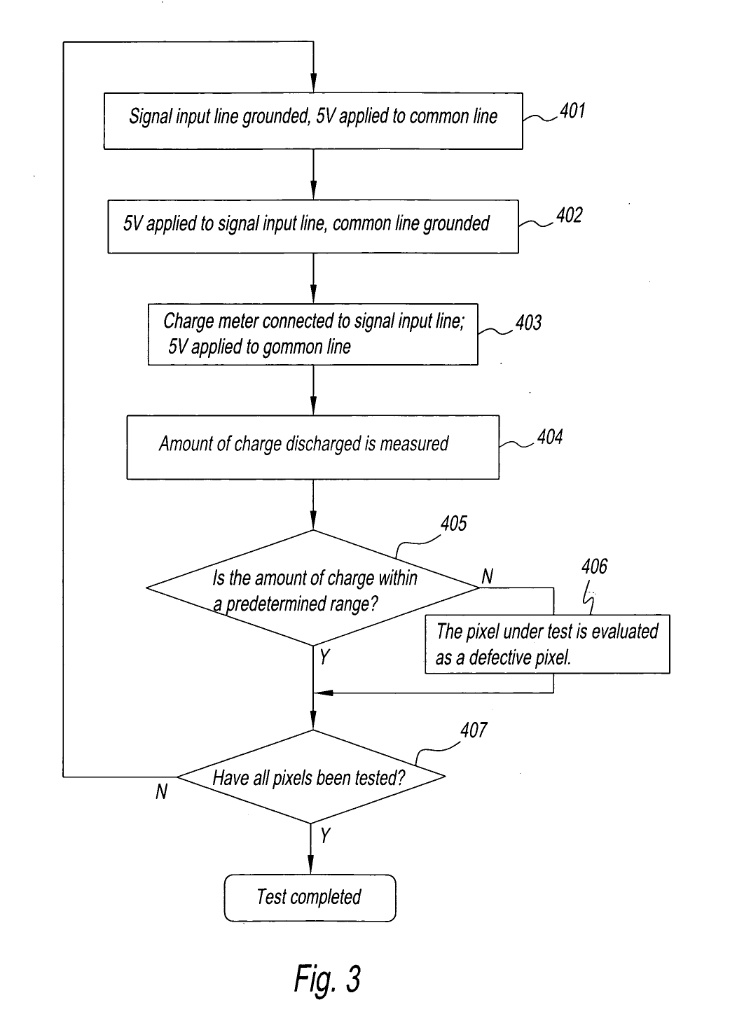

Next, the operation of testing apparatus 100 will be described while referring to FIG. 3.

First, signal input line 211 and power source 101 are connected by switching element 103. The output of power source 101 is set at 0 V, that is, at ground potential. Moreover, the output voltage of power source 105 is set at 5 V. Under this state, ON voltage is supplied to control lines 212 and 214. As a result, the pixel selected as the pixel under test is pixel 230 disposed where control line 214 intersects (column 1 of row 1) signal line 218 connected to transistor 220 controlled by control line 212.

The phrase “ON voltage” in the present Application means the voltage when the switching element is in a conducting state (ON state), that is, a voltage of threshold voltage or higher. Testing device 100 supplies ON voltage of 8 V to control line 214 in order to turn on transistor 231.

On the other hand, the voltage that turns off the switching element is the “OFF voltage.” For instance, an OFF voltage of −5 V is supplied to control line 215, which is not connected to pixel under test 230, and pixels (240, 260, etc) connected to control line 215 are brought to a non-selected state. The voltage and polarity of the ON voltage and OFF voltage vary with the transistor channel and type; therefore, they can be selected as needed in accordance with the transistor specification.

We return now to the description of the operation of testing apparatus 100. Transistor 220 is turned on and signal input line 211 and signal line 218 are brought to a conducting state by applying ON voltage to control line 212. Moreover, transistor 231 of pixel under test 230 is turned on and control line 218 and liquid crystal element 233 are brought to a conducting state by applying ON voltage to control line 214. Therefore, electrode 304 of liquid crystal element 233 (electrode on the source terminal side of transistor 231 is brought to ground potential. On the other hand, opposing electrode 300 is connected to control line 217 that is applying a voltage of 5 V. As a result, a voltage of −5 V (voltage of electrode 304 seen from electrode 300 connected to common line 217) is applied to liquid crystal element 233, a positive charge is fed to electrode 300, and a negative charge is fed to electrode 304 (step 401). This state is maintained for 100 microseconds and liquid crystal element 233 is charged (first charging step).

Then the output voltage of power source 105 is set at ground potential and the output voltage of power source 101 is set at 5 V. As a result, this time electrode 304 is at ground potential and electrode 300 is at 5 V; therefore, a voltage of 5 V and of a polarity which is opposite to that during the first charging step is applied to liquid crystal element 233 (step 402). This state is maintained for 100 microseconds and liquid crystal element 233 is charged to the opposite polarity (second charging step). The retention time can be set as needed based on the electrical properties, such as response, of liquid crystal element 233 under test.

Once the second charging step is over, OFF voltage is applied to control line 214 and transistor 231 is turned off. Then the output voltage of power source 101 is set at 0 V and the output voltage of power source 105 is set at 5 V (step 403). Signal line 218 and signal input line 211 are in a conducting state with power source 101. Therefore, the charge that has accumulated in the parasitic capacitor of signal line 218, etc. is discharged. The charge that has accumulated in liquid crystal 233 separated from signal line 218 is maintained. Then charge meter 102 is at rest and switch 103 is switched to the side of meter 102.

Under these circumstances, ON voltage is applied to control line 214 and transistor 231 of pixel under test 230 is turned on again. As a result, the charge that has accumulated in liquid crystal element 233 is charged through transistor 231 to signal line 218. The charge that has been discharged flows through signal input line 211 into charge meter 102. Charge meter 102 measures the amount of charge that flows for 100 microseconds beginning when discharge starts (step 404). It takes 10 milliseconds for liquid crystal element 233 to reach the steady state and it should therefore be noted that the amount of charge measured in step 404 is not the steady-state amount of charge, but rather the amount of charge immediately after the field applied to liquid crystal 233 has been reversed (measuring step).

It should further be noted that liquid crystal element 233 maintains the voltage charged in the second charging step (5 V) when discharge starts, and that the voltage of electrode 300 as seen from the ground potential of testing apparatus 100 becomes 10 V as a result of the voltage applied to common line 217 being changed at step 403. Thus, it is possible to obtain a high measurement value of the S/N ratio by changing the voltage of common line 217 during the measurement.

Next, charge meter 102 evaluates whether or not the measurement results are within a predetermined range (step 405). Dynamic electrical properties are poor in the case of liquid crystal elements with a poor response to changes in the status of the group of molecules as a result of orientation films 301 and 303 being improperly formed, the poor quality of liquid crystal material 302, and the like; therefore, the charge to be measured deviates from the range to be measured for normal liquid crystal elements. If the measurement results are not within a predetermined range, charge meter 102 evaluates that pixel under test 230 is defective and the position of the pixel under test, the measured amount of charge, and similar parameters are recorded (step 406) (evaluation step). The testing of pixel 230 in row 1 of column 1 is thereby completed.

The same testing procedure is performed in succession on pixel 240 of row 1 of column 2, the pixel in row 1 of column 3 (not illustrated), and so forth. Once all of the pixels in row 1 have been completed, all of the pixels in the second row are tested in succession on the order of pixel 250 in row 2 of column 1, pixel 260 in row 2 of column 2, and so forth. The tests on display panel 200 are completed when each pixel in the third row, each pixel in the fourth row, and so forth has been similarly tested (step 407).

By means of the above-mentioned test, a relatively large voltage is applied to liquid crystal element 233, but voltage of the opposite polarity of the first charging step is applied during the second charging step; as a result, a deterioration of liquid crystal element 233 can be prevented. The voltage applied during the first charging step and the voltage applied during the second charging step should be the same absolute voltage but of the opposite polarity.

The order in which the pixels were tested was by row, but the tests are not limited to this order. For instance, the pixels can be tested by being scanned in the direction of the rows so that once pixel 230 in row 1 of column 1 is tested, the other pixels are tested in the order of pixel 250 in row 2 of column 1, the pixel in row 3 of column 1, and so forth. Moreover, it is possible to test only a predetermined sample of pixels rather than all pixels when the production steps are very stable and reliable.

Another embodiment of the present disclosure will be described. The second embodiment differs from the first embodiment in terms of the testing procedure, but the structure and connection status of testing apparatus 100 and liquid crystal display panel 200 are the same as in FIG. 1.

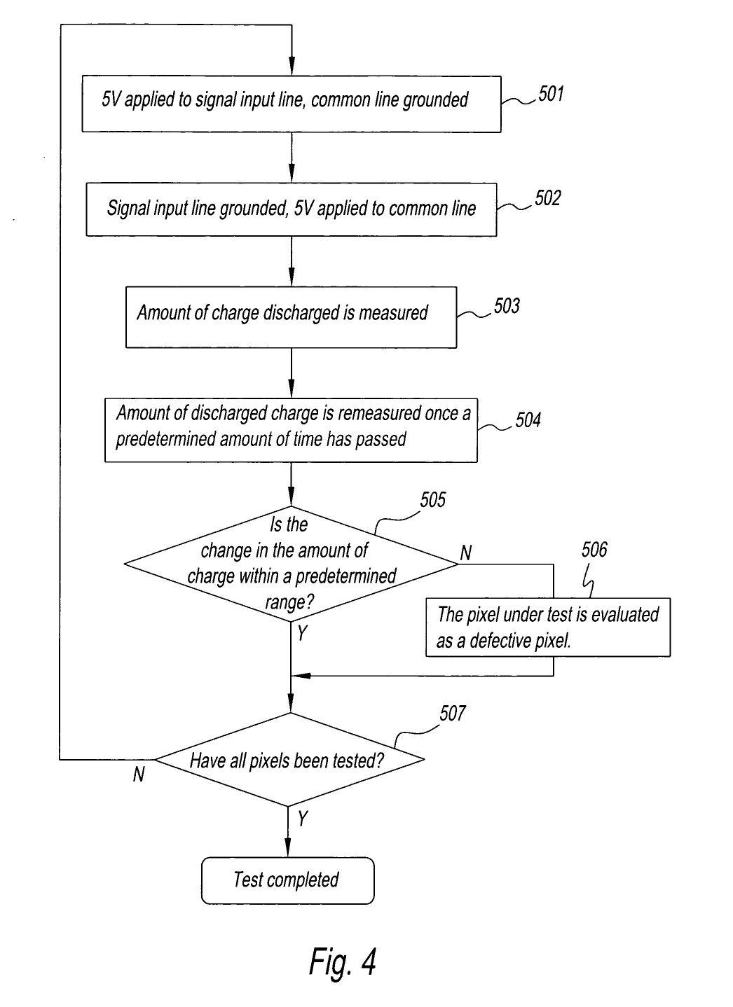

Next, the testing procedure of the second embodiment will be described while referring to the flow chart in FIG. 4.

First, signal input line 211 and power source 101 are connected by switching element 103. The output of power source 101 is set at 5 V and the output voltage of power source 105 is set at 0 V. Under these circumstances, ON voltage is supplied to control lines 212 and 214. As a result, the pixel selected as the pixel under test is pixel 230 disposed where control line 213 intersects signal line 218 connected to transistor 220 controlled by control line 212 (column 1 of row 1).

Transistor 220 is turned on and signal input line 211 and signal line 218 are brought to a conducting state by applying ON voltage to control line 212. Moreover, transistor 231 of pixel under test 230 is turned on and signal line 218 and liquid crystal element 233 are brought to a conducting state by applying ON voltage to control line 214. Therefore, electrode 300 of liquid crystal element 233 (electrode on the source terminal side of transistor 231) becomes 5 V. On the other hand, the potential of opposing electrode 304 connected to common line 217 is ground potential. Consequently, a voltage of 5 V is applied to liquid crystal element 233, and a positive charge is supplied to electrode 304, while a negative charge is supplied to electrode 300 (step 501) (charging step).

Once this state has been maintained for 100 microseconds, OFF voltage is applied to control line 214 and transistor 230 is turned off. The holding time is selected based on the response of liquid crystal element 233 of the liquid crystal display panel under test. Then the output voltage of power source 101 is set at 0 V and the output voltage of power source 105 is set at 5 V (step 502). Signal line 218 and signal input line 211 are in a conducting state with power source 101; therefore, the charge that has accumulated as the parasitic capacity of signal line 218, etc. is discharged. The charge that has accumulated in liquid crystal element 233 that is separated from signal line 218 is maintained. Then charge meter 102 is reset and switch 103 is switched to the side of charge meter 102.

Under these circumstances, ON voltage is applied to control line 214 and transistor 231 of pixel under test 230 is turned on again. As a result, the charge that has accumulated in liquid crystal element 233 is discharged through transistor 231 to signal line 218. The charge that has been discharged flows through signal input line 211 to meter 102. Meter 102 performs the first measurement of the amount of charge once 100 microseconds have passed since discharge was started (step 503). The second measurement of the amount of charge is performed when 100 milliseconds have passed (step 504) (measuring step).

It should be noted that the liquid crystal element 233 holds the voltage (5 V) that was discharged during the charging step when discharge is started and the voltage of electrode 300, as seen from the ground potential of testing apparatus 100, becomes 10 V as a result of the voltage applied to common line 217 being changed at step 502. Thus, it is possible to obtain a high measurement value of the S/N ratio by changing the voltage of common line 217 during measurement.

Next, charge meter 102 finds the difference between the first measured charge and the second measured charge (change over time). Moreover, it evaluates whether or not the resulting amount of change is within a predetermined range (step 505). The response of the electrostatic capacity (dynamic property) is poor in the case of liquid crystal elements with a poor response to changes in the status of the group of molecules as a result of orientation films 301 and 303 being improperly formed, the poor quality of liquid crystal material 302, and for similar reasons; therefore, the charge that will be measured deviates from the range to be measured for normal liquid crystal elements. If the measurement results are not within a predetermined range, charge meter 102 evaluates that pixel under test 230 is defective and the position of the pixel under test, the measured amount of charge, and the like are recorded (step 506) (evaluation step). The testing of pixel 230 in row 1 of column 1 is thereby completed.

The same testing procedure is performed in succession on pixel 240 in row 1 of column 2, the pixel in row 1 of column 3 (not illustrated), and so forth. Once the testing of all of the pixels in row 1 has been completed, all of the pixels in the second row are tested in succession in the order of pixel 250 in row 2 of column 1, pixel 260 in row 2 of column 2, and so forth. The tests on display panel 200 are completed when each pixel in the third row, each pixel in the fourth row, and so forth have been similarly tested (step 507).

The order in which the pixels were tested was by row, but the tests are not limited to this order. For instance, the pixels can be tested by being scanned in the direction of the rows so that once pixel 230 in row 1 of column 1 is tested, the other pixels are tested in the order of pixel 250 in row 2 of column 1, the pixel in row 3 of column 1, and so forth. Moreover, it is possible to test only a predetermined sample of pixels rather than all pixels when the production steps are very stable and reliable.

Moreover, the timing of the first and second measurement can be changed as needed in accordance with the response of liquid crystal element 233. In this case, it is possible to increase the amount of change and thereby increase the S/N ratio of the measurement and perform very reliable testing by performing the first measurement immediately after starting discharge, and then performing the second measurement a sufficient amount of time (for instance, 1 millisecond) after the first measurement, preferably once the steady state has been reached.

In addition, when the second measurement is performed under the steady state, the measurement results that are obtained can be regarded as the results of measuring static properties; therefore, it is possible to conduct the measurements in line with defect tests based on static properties by evaluating whether the absolute value of the measurement result is within a predetermined range.

It is also possible to conduct precision testing and defect mode evaluation by measuring the properties between the time immediately after starting discharge and the time when the steady state has been reached and more precisely to trace changes over time.

By means of the present embodiment, the change in the amount of charge of the discharged current was found by a charge meter, but it is also possible to use an ammeter in place of the charge meter and find defects in the dynamic properties of a pixel from changes in the amount of current. The phrase “changes over time in the charge that is discharged” includes both changes in the amount of charge and changes in the amount of current.

The technological concept of the present disclosure was described in detail above while referring to specific working examples, but it is clear that persons skilled in the art to which the present disclosure belongs can make various changes or modifications without deviating from the intent and scope of the claims.

What is claimed is:

1. A method for testing a liquid crystal display panel wherein there are, disposed in matrix form, pixels comprising liquid crystal elements in which a liquid crystal material is sealed between opposing electrodes, said method comprising:
applying a first voltage between the opposing electrodes of the liquid crystal element of the pixel under test;
applying a second voltage of the opposite polarity of the first voltage between the opposing electrodes of the liquid crystal element of the pixel under test;
discharging the charge that has accumulated in the electrodes of the liquid crystal element of the pixel under test after applying said second voltage; and
measuring the amount of charge discharged.

2. The method for testing the liquid crystal display panel according to claim 1, wherein the absolute value of said first voltage is equal to the absolute value of said second voltage.

3. A method for manufacturing a liquid crystal display panel wherein there are, disposed in matrix form, pixels comprising liquid crystal elements in which a liquid crystal material is sealed between opposing electrodes, said method for manufacturing a liquid crystal display panel comprises checking for defects in the liquid crystal elements, wherein said step for checking comprises:
applying a first voltage between the opposing electrodes of the liquid crystal element of the pixel under test;
applying a second voltage of the opposite polarity of the first voltage between the opposing electrodes of the liquid crystal element of the pixel under test;
discharging the charge that has accumulated in the electrodes of the liquid crystal element of the pixel under test after applying said second voltage; and
measuring the amount of charge discharged.

4. A method for testing a liquid crystal panel wherein there are, disposed in matrix form, pixels having liquid crystal elements in which a liquid crystal material is sealed between opposing electrodes, said method comprising:
applying test voltage between the opposing electrodes of the liquid crystal element of the pixel under test; and
discharging the charge that has accumulated in the electrodes of the liquid crystal element and finding changes over time in the amount of charge discharged.

5. The method for testing a liquid crystal panel according to claim 4, wherein the changes over time in the charge discharged are found from changes in the status immediately after discharging starts and the status at a predetermined amount of time after discharge starts.

6. A method for manufacturing a liquid crystal display panel wherein there are, disposed in matrix form, pixels comprising liquid crystal elements in which a liquid crystal material is sealed between opposing electrodes, said method comprises checking for defects in the liquid crystal element, wherein said checking comprises:
applying test voltage to the opposing electrodes of the liquid crystal element of the pixel under test;
discharging the charge that has accumulated in the electrodes of the liquid crystal element;
measuring the amount of discharged charge at predetermined time intervals beginning when discharge starts; and
finding the change in the amount of charge.

7. An apparatus for testing a liquid crystal display panel comprising multiple control lines; multiple signal lines intersecting the multiple control lines; pixels that have liquid crystal elements disposed where the control lines and signal lines intersect; and switching elements for controlling the connection status between the signal lines and liquid crystal element based on the signals from the control lines; and a common line that applies the reference potential of a liquid crystal element, said apparatus comprising:
a power source;
a charge meter; and
a control device that executes a process comprising: connecting the power source to the common line of the pixel under test and applying voltage between the opposing electrodes of the liquid crystal element of the pixel under test; connecting the power source to the signal line to which the pixel under test is connected and applying voltage between the opposing electrodes of the liquid crystal element of the pixel under test; and discharging the charge that has accumulated in the electrodes of the liquid crystal element of the pixel under test and measuring the amount of charge discharged using the charge meter.

8. An apparatus for testing a liquid crystal display panel comprising multiple control lines, multiple signal lines intersecting the multiple control lines, and pixels disposed where the control lines and signal lines intersect, wherein the pixels comprise liquid crystal elements and switching elements for controlling the connection status between the signal lines and liquid crystal elements based on the signals of the control lines, said apparatus comprising:
a power source;
a charge meter; and
a control device that connects the power source to the signal line to which the pixel under test is connected, applies a voltage between the opposing electrodes of the liquid crystal element of the pixel under test, discharges the charge that has accumulated in the electrodes of the liquid crystal element of the pixel under test, measures the amount of charge discharged at predetermined time intervals using the charge meter, and finds the change in the amount of charge.
